(19) United States
(12) Patent Application Publication
(10) Pub. No.: US 2008/0145650 A1
(43) Pub. Date: Jun. 19, 2008

(54) DOUBLE PLASMA UTBOX

(76) Inventors: Ionut Radu, Crolles (FR); Audrey Lambert, Grenoble (FR)

Correspondence Address: WINSTON & STRAWN LLP;PATENT DEPARTMENT, 1700 K STREET, N.W., WASHINGTON, DC, 20006, US

(21) Appl. No.: 11/755,560

(22) Filed: May 30, 2007

(30) Foreign Application Priority Data
Dec. 18, 2006 (FR) FR 0655608

(51) Int. Cl. H01L 21/30; B32B 9/00

(52) U.S. Cl. 428/336; 438/458; 257/E21.211

(57) ABSTRACT

A method for bonding two substrates carried out in materials chosen from among semiconductor materials, includes the steps of bonding the two substrates by thermal treatment after plasma activation of the surface to be bonded for each substrate. One of the surfaces to be bonded includes an oxide layer. The plasma activation of the surface that has the oxide layer is carried out under an atmosphere containing oxygen, while the plasma activation of the surface to be bonded of the second substrate is carried out under an inert atmosphere.

### BACKGROUND

The present invention relates to a method for bonding two substrates carried out in materials chosen from among semiconductor materials. In general, the method implements a step of bonding two substrates by thermal treatment after the substrates have been subjected by plasma activation of at least one of the surfaces of the substrates to be bonded. In particular, one of the surfaces to be bonded includes an oxide layer.

Methods of this type are already known. Here, “bonding” is understood to refer to bonding by molecular adhesion, where two perfectly smooth surfaces adhere to each other without using adhesive—this being possible at room temperature. The quality of the bonding is particularly characterized by the bonding energy, which expresses the strength of the bond between two substrates bonded together.

To consolidate two substrates by molecular adhesion bonding, the assembled substrates must undergo a heat treatment. Such a heat treatment allows the bonding energy of the two substrates to be brought to a value on the order of at least 500 mJ/m², which may correspond to typically desired values.

Conventionally, such a heat treatment is generally carried out at a temperature on the order of at least 900° C. (which defines in the scope of this text the “high temperature” field”). In the case of bonding between a Si substrate and a Si or SiO₂ substrate, the bonding energy is maximized with a treatment carried out at temperatures around of 1100-1200° C. “Plasma activation” of a surface to be bonded is defined as exposure of this surface to a plasma (this may be done in particular under vacuum or at atmospheric pressure) prior to put the surfaces to be bonded in contact.

More precisely, in known activation techniques, the surface of a substrate to be activated is exposed to plasma during the exposure step in which the exposure parameters are controlled so that they are each set at a given respective value, which remains fixed during the plasma activation.

In first order, the “exposure parameters” are:

the power density. This is the density of power supplying the plasma, which corresponds to a power density per unit of surface (W/cm²) and that will also be designated by the simple term of “power” in this text.

the pressure (pressure in the chamber containing the plasma, expressed in mTorr),

the nature and flow of gas (expressed in sccm: standard cubic centimeter per minute) supplying this chamber.

Such activation particularly allows bonding by molecular adhesion to be carried out by obtaining significant bonding energies without necessitating a heat treatment at high temperatures. In fact, plasma activation leads to high bonding energies between two substrates, at least one of which has been activated before bonding after heat treatments carried out over relatively short durations (for example on the order of 2 hours) at relatively low temperatures (for example on the order of 600° C. or less).

Such activation is therefore advantageous to stabilize a structure comprising two bonded substrates, in the case where one wishes to avoid subjecting the structure to too high temperatures (particularly in the case of heterostructures, which are defined as structures comprising layers made of materials having thermal expansion coefficients that are substantially different).

Such activation may also be advantageous for obtaining significant bond strengths at a given temperature. Such activation is therefore advantageous, for example, for fabricating multilayer structures by bonding two substrates. The transfer methods (particularly SMART-CUT® type methods, of which a general description may be found in the article by G. Celler, Frontiers of Silicon-on-Insulator, Journal of Applied Physics, Vol. 93, no. 9, May 1, 2003, pages 4955-4978), or of the BESOI (Bond Etch Silicon On Insulator) type methods in which two substrates are bonded and then, the surplus material of one of the substrates is eliminated by etching) are examples which may benefit from plasma activation for bonding.

To fully exploit the effects of plasma treatment for each bonding, the conventional method encountered in literature (particularly in the documents Effects of plasma activation on hydrophilic bonding of Si and SiO₂, T. Suni et al., Electrochemical Society Proceedings Vol. 2001-27, Page Nos. 22-30 and in U.S. Pat. No. 6,645,828 by Farrens et al.) consists of activating by plasma the two substrates to be bonded.

More rarely, only one of the two surfaces is exposed to plasma since the bonding energy is low. In the case of Si/SiO₂ bonding, it is generally the oxide that is treated by plasma (see Suni et al. article mentioned above). Different gases are today utilized in plasma treatments to activate the surfaces of the wafers before putting them in contact, as for example, oxygen, nitrogen and argon, but generally, the two surfaces to be bonded are treated in the same manner with the same plasma treatment.

There is a need, therefore, for enhanced bonding of such surfaces, and this is now provided by the present invention

### SUMMARY OF THE INVENTION

The invention improves known bonding techniques implementing plasma activation. It also reduces the number of defects present on a substrate, or even completely eliminate these defects. In particular, invention increases the bonding energy obtained after plasma activation on such surfaces.

The invention relates to a method for providing enhanced molecular bonding of first and second substrates of semiconductor materials, wherein a first substrate includes an oxide layer forming a surface of the substrate, which comprises plasma activating the surface oxide layer of the first substrate under an atmosphere containing oxygen; plasma activating the surface of the second substrate under an inert atmosphere; and bonding the surfaces together by contacting their plasma activated surfaces together and conducting a thermal treatment to form a bonded structure that provides enhanced bonding compared to a bonded structure of the same substrates where each surface is plasma activated in the same manner.

Preferably, the substrate that includes the surface oxide layer is a donor substrate for supplying a useful layer of the semiconductor material and the oxide layer and the second substrate is a receiver substrate that receives the useful and oxide layers. This enables the oxide and useful layers to conveniently be transferred from the donor substrate to the receiver substrate to for new structures. In particular, Ultra Thin Buried Oxide (UTBOX) layers having a thickness of between 50 and 1000 Å can be transferred according to this process with the transferred useful layer having no visually observable holes or incompletely transferred regions.

The invention also relates to an assembly for forming a Silicon on Insulator (SOI) structure which comprises first and second substrates of semiconductor materials, wherein a first substrate includes an oxide layer forming a surface of the substrate and having been plasma activated under an atmosphere containing oxygen; and the second substrate has a surface that has been plasma activated under an inert atmosphere; wherein the surfaces are molecularly bonded together by contacting their plasma activated surfaces together and conducting a thermal treatment to form a bonded structure that provides enhanced bonding compared to a bonded structure of the same substrates where each surface is plasma activated in the same manner, so that the structure includes an UTBOX layer having a thickness of between 50 and 1000 Å.

The first substrate can be a donor wafer while the second substrate can be a receiver wafer. Also, the donor wafer can include a zone of weakness that can be split to remove the donor wafer except for the useful and UTBOX layers that are transferred to the receiver substrate to form the SOI structure.

### BRIEF DESCRIPTION OF THE DRAWINGS

The invention will be better understood upon reading the following detailed description done with reference to the attached drawings in which:

FIG. 1 is a graph that compares the number of defects counted after detachment of a transfer of a layer from a donor substrate bonded with a receiver substrate for an oxide layer of 250 Å, the bonding having been done with a plasma activation during which:

the donor substrate, oxidized at the surface, was activated by an oxidizing plasma, and

the silicon receiver substrate was activated by one of two types of plasma under an atmosphere comprised of an inert gas (nitrogen or argon), or was not activated.

FIG. 2 is a graph that compares the number of defects counted after detachment in the scope of a transfer of a layer from a donor substrate bonded with a receiver substrate for a layer of oxide of 125 Å, the bonding having been performed with a plasma activation during which:

the donor substrate, oxidized at the surface, was activated by an oxidizing plasma, and

the silicon receiver substrate was activated by one of two types of plasma under an atmosphere comprised of an inert gas (nitrogen or argon), or was not activated.

FIG. 3 compares the bonding energies obtained between two substrates that are bonded together, one of the substrates being covered by an oxide layer and having been activated before bonding by oxidizing plasma, using:

different types of non-oxidized substrate preparations (activation by a nitrogen or argon plasma, and without plasma activation), and

different thicknesses of the oxide layer covering the surface oxidized substrate (1000 Å, 500 Å, 250 Å and 125 Å).

FIG. 4 is a graph that compares the number of defects counted after detachment of a transfer of one layer from a donor substrate bonded with a receiver substrate for an oxide layer of 250 Å, the bonding having been carried out with a plasma activation during which:

the oxidized surface of the donor substrate was activated by a plasma from one of two types of plasma under a neutral atmosphere (nitrogen or argon) or by an oxidizing plasma, or was not activated, and

the receiver substrate in non-oxidized silicon was not activated.

### DETAILED DESCRIPTION OF THE PREFERRED EMBODIMENTS

The invention generally relates to a method for bonding two substrates made of materials chosen from among semiconductor materials. This method comprises:

a step of bonding the two substrates by heat treatment,

a plasma activation of the surface to be bonded of each substrate, wherein the surface to be bonded of one of the substrates is comprised of an oxide layer, and the plasma activation of the oxide layer is carried out under an atmosphere containing oxygen, while the plasma activation of the surface to be bonded of the other substrate is carried out under an inert atmosphere.

Preferred, but non-limiting, aspects of this method are the following:

the substrate whose surface is comprised of an oxide layer is the donor substrate for a layer transfer to a receiver substrate,

the oxide layer is obtained by thermal oxidation of the donor substrate,

the oxide layer is deposited on the donor substrate,

the transfer allows a SOI type structure to be obtained,

this SOI comprises an UTBOX thin layer, whose thickness is between 50 and 1000 Å and preferably is less than 500 Å,

the receiver substrate is silicon,

the neutral gas is argon,

the power density during activation by a plasma under an atmosphere comprising argon is 0.4 W/cm²,

the neutral gas is nitrogen,

the power density during activation by plasma under an atmosphere comprising nitrogen is 0.8 W/cm²,

the receiver substrate is subjected to a cleaning step before the plasma activation step, the donor substrate is subjected to a cleaning step before the plasma activation step,

the bonding heat treatment is performed at low temperature,

the bonding heat treatment is performed between 200° C. and 600° C.,

the bonding heat treatment is performed over a short duration,

the bonding heat treatment is performed for a short duration of about 30 minutes to 5 hours and preferably at approximately 2 hours.

The invention also relates to an SOI type structure obtained by the transfer to a receiver substrate of a thin layer removed from a donor substrate, after bonding obtained by plasma activation according to a method of the type mentioned above, characterized in that the invention has an UTBOX (Ultra Thin Buried Oxide) type layer.

Preferred, but non-limiting, aspects of this structure are the following:

the thickness of the buried oxide layer is between 50 and 1000 Å, and preferably is less than 500 Å,

for a thickness of the buried oxide layer of approximately 250 Å, this layer has between 0 and 10 defects,

for a thickness of the buried oxide layer of approximately 125 Å, this layer has between 0 and 310 defects,

for a thickness of the buried oxide layer of approximately 1000 Å, and for a plasma activation under neutral atmosphere carried out with argon, the bonding energy at room temperature is approximately 0.175 J/m²,

for a thickness of the buried oxide layer of approximately 500 Å, and for a plasma activation under neutral atmosphere carried out with argon, the bonding energy at room temperature is approximately 0.180 J/m²,

for a thickness of the buried oxide layer of approximately 250 Å, and for plasma activation under neutral atmosphere carried out with argon, the bonding energy at room temperature is approximately 0.200 J/m²,

for a thickness of the buried oxide layer of approximately 125 Å, and for plasma activation under neutral atmosphere carried out with argon, the bonding energy at room temperature is approximately 0.200 J/m²,

for a thickness of the buried oxide layer of approximately 1000 Å, and for plasma activation under neutral atmosphere carried out with nitrogen, the bonding energy at room temperature is approximately 0.235 J/m²,

for a thickness of the buried oxide layer of approximately 500 Å, and for plasma activation under neutral atmosphere carried out with nitrogen, the bonding energy at room temperature is approximately 0.258 J/m²,

for a thickness of the buried oxide layer of approximately 250 Å, and for plasma activation under neutral atmosphere carried out with nitrogen, the bonding energy at room temperature is approximately 0.270 J/m²,

for a thickness of the buried oxide layer of approximately 125 Å, and for a plasma activation under neutral atmosphere carried out with nitrogen, the bonding energy at room temperature is approximately 0.262 J/m².

The bonding method according to the invention may be implemented for the transfer of a thin layer in view of making SOI (Silicon On Insulator) type substrates, made by molecular adhesion bonding with the implementation of a layer transfer (for example by a SMART-CUT® or other layer transfer method).

More precisely, an advantageous application of the invention relates to the manufacturing of SOI substrates more precisely UTBOX containing substrates having very thin insulating layers, whose thickness is less than 500 Å, for example around a hundred A. A particular non-limiting example of the invention relates to UTBOX substrates for which good results have been obtained. However, it is explained that the invention can also be applied to thick Buried Oxide (BOX), that is, one having a thickness greater than 500 Å.

Indeed, when the buried oxide layer of such structures is very thin, one may observe problems with defectivity (areas not transferred, voids, bubbles, and blisters) within the layer transferred. According to the invention, these problems are eliminated or drastically reduced.

The invention is generally applied to the bonding of two substrates of a semiconductor material. Each of these materials may be silicon, or another semiconductor material. Typically, one of the surfaces to be bonded of the two substrates may in addition have been oxidized prior to activation. As will be seen herein, activation is carried out on each of the two surfaces to be bonded.

One may also explain that the invention allows bonding to be performed, particularly in the scope of a transfer method for a thin layer of a semiconductor material from a “top” wafer forming the donor substrate to a “base” wafer forming the receiver substrate. The term “thin layer” refers to a layer of several hundreds to several thousands Angstroms (Å) in thickness.

In this application to transfer methods, bonding is performed after activation between the oxide surface of the donor substrate and a free surface of the receiver substrate. This transfer method may particularly be performed according to the SMART-CUT® method implementing an implantation of atomic or ions species before bonding to create in the thickness of the donor substrate an zone of weakness for subsequent detachment of the thin and oxide layers at the level of zone of weakness after bonding. The bonding step results in the formation of an assembly where the donor substrate and receiver substrate are bonded together. This assembly then can be further processed by various techniques to for the final SOI structure. This is conventionally done by removing a portion of the donor wafer other than the thin and oxide layers that are left behind bonded to the receiver substrate.

As in the case of some known methods, the invention brings the activation of two surfaces of substrates to be bonded by plasma into play. In the invention, a specific plasma activation of the surface to be bonded of each substrate is implemented, the surface to be bonded of only a first of the two substrates comprising of an oxide layer. Preferably, plasma activation of the oxide layer is carried out under an atmosphere containing oxygen, and plasma activation of the surface to be bonded of the second substrate is carried out under an inert atmosphere.

The following description illustrates examples of bonding methods that transfer a layer from a donor substrate to a receiver substrate, the layer being detached according to a SMART-CUT® type method. However, the invention is understood as relating to the bonding step itself and the layer transfer is only a particular illustration.

### Treatment of the Receiver Substrate

Generally, the power values specified in the following description are given for applications for wafers with a diameter on the order of 200 mm. However, the present invention also applies to wafers with a diameter on the order of 300 mm or more, by adapting the power of the plasma (or the power density values). This is within the ability of a skilled artisan having this disclosure before them. Generally, the power density is between 0.035 W/cm² and 10 W/cm², preferably 0.4 W/cm² for argon, and 0.8 W/cm² for nitrogen, and 0.8 W/cm² for oxygen.

The surface of the receiver substrate is not comprised of an oxide layer, and is preferably Silicon. Prior to plasma activation, the surface to be bonded of the substrate may have been cleaned, for example with ozone and/or a mixture of RCA. The surface of the receiver substrate is then subjected to plasma activation under neutral atmosphere, for example containing argon or nitrogen, under the following specific experimental conditions:

For treatment under an atmosphere containing argon:

the strength is between 25 and 2500 W, preferably, it is from 125 W for a 200 mm wafer or approximately 200 W for a 300 mm wafer (corresponding to a power density of 0.4 W/cm²),

the pressure is between 20 mTorr and 100 mTorr, preferably 50 mTorr,

the gas flow is between 0 and 100 sccm, preferably 100 sccm, AND

the exposure duration is between 5 sec and 5 min, preferably 30 seconds.

For treatment under an atmosphere containing nitrogen:

the power is between 25 and 2500 W, preferably 250 W (corresponding to a power density of 0.8 W/cm²),

pressure is between 20 mTorr and 100 mTorr, preferably 50 mTorr,

the gas flow is between 0 and 100 sccm, preferably 100 sccm, and

the exposure duration is between 5 sec and 5 min, preferably 30 seconds.

During plasma activation, the power density supplying the plasma is adapted to the gas utilized. In fact, as argon atoms are larger than nitrogen atoms, the power retained to implement argon plasma will be more limited than for nitrogen plasma, in order to prevent a spraying effect of the argon.

### Treatment of the Oxide Surface to be Bonded of the Donor Substrate

The surface to be bonded of the donor substrate is comprised of a thin layer of oxide, on the order of 100 to 5000 Å in thickness, preferably less than 500 Å or even less than 250 Å in thickness (particularly in the case of a very thin layer intended to comprise a UTBOX type structure). Prior to plasma activation, the surface to be bonded of the substrate may be cleaned, for example with ozone and/or a mixture of RCA.

Treatment by plasma activation is carried out by using oxygen gas according to the following experimental conditions:

the power is between 25 and 2500 W, preferably 250 W,

the pressure is between 20 mTorr, preferably 50 mTorr,

the gas flow is between 0 and 100 sccm, preferably 75 sccm, and

the exposure duration is between 5 sec and 5 min, preferably 30 to 45 sec.

### Step of Bonding of Two Wafers

The two wafers are put in contact and then subjected to a low temperature heat treatment (between 25° C. and 1100° C.), preferably between 200° C. and 600° C., to strengthening the bonding energy, for a duration going from 30 min to 5 hours, the exposure duration preferably being about 2 hours.

The inventive method presented is in fact developed to optimize activation of the surfaces of substrates to be bonded. An additional advantage of this method resides in the reduction or even elimination of defects (areas not transferred, voids, bubbles, and blisters) within the thin layer that may be present after transfer of this layer on the substrate.

Furthermore, once the bonding step has been carried out, a step of thinning of the donor substrate is carried out, for example according to the SMART-CUT® method, or even by etching of the donor substrate. In fact, the present invention may be applied to making complex substrates (of the SOI type for example) by a SMART-CUT® method, or also by a BESOI method. The invention also applies to substrates comprising integrated circuits that cannot undergo high temperature heat treatments and would therefore necessitate plasma bonding.

The experimental conditions of the bonds performed in order to obtain the results provided in the figures were the following:

oxidation (for example by heating) to obtain an oxide layer with a given thickness over the surface to be treated of the donor substrate.

implantation of the donor substrate with hydrogen alone (energy 80 keV, dose 7.6 10¹⁶ atoms/cm²) across the surface to be bonded,

cleaning of the two surfaces to be bonded by ozone and/or RCA type cleaning,

plasma activation under an atmosphere comprised of oxygen (flow of 75 sccm, pressure of 50 mTorr, power density of 250 W, duration of 30 sec) of the surface to be bonded of the donor substrate,

plasma activation under an atmosphere containing argon (flow of 100 sccm, pressure of 50 mTorr, power density of 125 W, duration of 30 sec) of the surface to be bonded of the receiver substrate,

bonding of the two surfaces to be bonded by molecular adhesion,

annealing between 200° C. to 600° C. to stabilize the bonding.

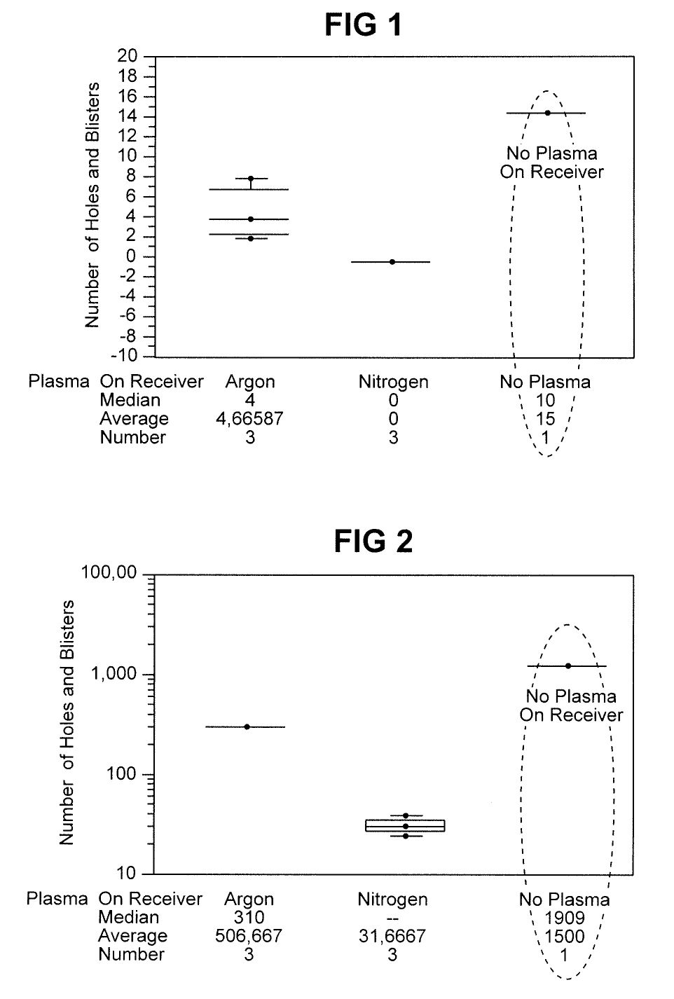

As is seen in FIG. 1, approximately 15 defects (areas not transferred, voids, bubbles, and blisters) may be detected on the layer transferred after the application of a SMART-CUT® method if the receiver substrate was not plasma activated, while 4 defects are counted in the case of argon plasma activation, and no defects in the case of nitrogen plasma activation.

The number of defects is therefore significantly reduced when the receiver substrate is subjected to plasma activation in an atmosphere containing an inert gas.

FIG. 2 shows similar results. More than 1000 defects are detected in the case where the receiver substrate was not plasma activated, while only approximately 300 defects are counted in the case of plasma treatment under an atmosphere containing argon, and about thirty defects in the case of plasma treatment under an atmosphere containing nitrogen.

The presence of a higher number of defects in the case of FIG. 2 is due to the fact that the oxide layer has a much thinner thickness than in the case of FIG. 2. However, the total number of defects is significantly lower when the surface to be bonded of the receiver substrate has received beforehand plasma treatment under a neutral atmosphere.

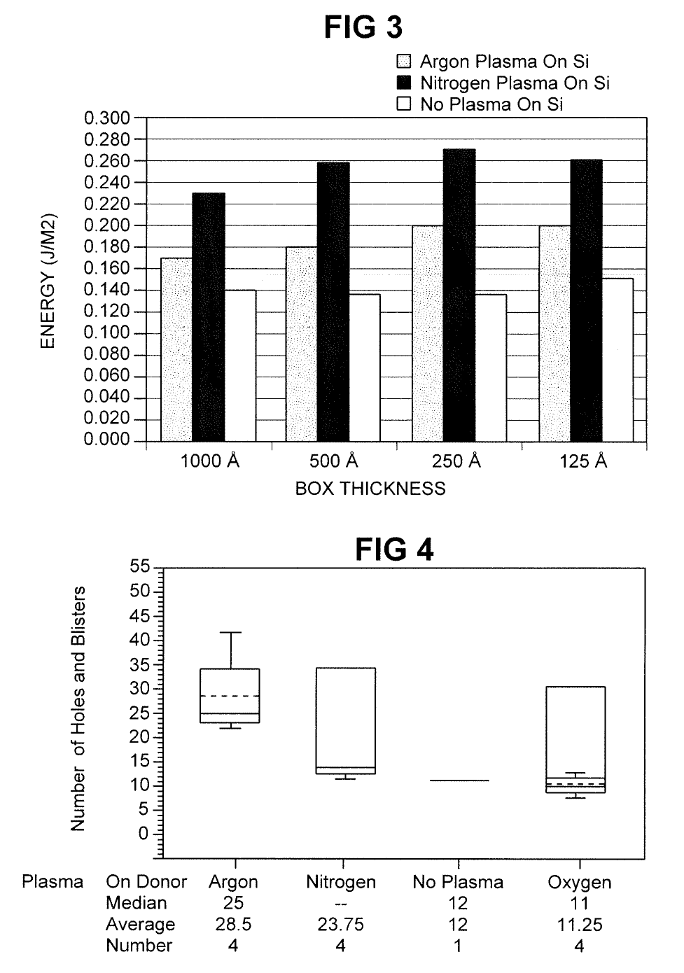

FIG. 3 shows that, when the surface of the oxidized donor substrate was activated by an oxidizing plasma, whatever the thickness of the oxide layer of the donor substrate, the bonding energy is higher when the surface to be bonded of the receiver substrate was treated beforehand to bonding by plasma activation (by a neutral gas) than when it was not activated by plasma. However, the effect of this plasma activation depends on the thickness of the layer, as well as the neutral gas utilized (argon or nitrogen). No degradation of bonding energy was observed for the very thin oxide layers that were treated according to the invention.

FIG. 4 shows that activation of the oxidized surface of the donor substrate by an oxidizing plasma, the receiver substrate inactivated, provides better results in terms of defectiveness in comparison with treatments by argon and nitrogen plasma, which explains the choice of activation by an oxidizing plasma of the donor substrate.

The oxide layer at the surface of the donor substrate here has a thickness of 250 ∈. Indeed, a dozen defects are counted when the oxidized surface of the donor substrate was activated by an oxidizing plasma, on the order of about fifteen defects when the oxidized surface of the donor substrate was activated by a plasma under an atmosphere comprising nitrogen, and on the order of 25 defects when the oxidized surface of the donor substrate was activated by plasma under an atmosphere comprising argon.

In addition, the results obtained following activation of the oxidized surface of the donor substrate by an oxidizing plasma are also better in terms of defectiveness than those obtained when the surface was not activated beforehand.

What is claimed is:

1. A method for providing enhanced molecular bonding of first and second substrates of semiconductor materials, wherein a first substrate includes an oxide layer forming a surface of the substrate, which comprises:
plasma activating the surface oxide layer of the first substrate under an atmosphere containing oxygen;
plasma activating the surface of the second substrate under an inert atmosphere; and
bonding the surfaces together by contacting their plasma activated surfaces together and conducting a thermal treatment to form a bonded structure that provides enhanced bonding compared to a bonded structure of the same substrates where each surface is plasma activated in the same manner.

2. The method according to claim 1, wherein the substrate that includes the surface oxide layer is a donor substrate for supplying a useful layer of the semiconductor material and the oxide layer and the second substrate is a receiver substrate that receives the useful and oxide layers.

3. The method according to claim 2, wherein the oxide layer is provided by thermal oxidation of the donor substrate.

4. The method according to claim 2, wherein the oxide layer is provided by being deposited onto the donor substrate.

5. The method according to claim 2, wherein the donor wafer includes a zone of weakness and which further comprises splitting the donor wafer at the zone of weakness to transfer the oxide and useful layers from the donor substrate to the receiver substrate to form a SOI (Silicon On Insulator) structure.

6. The method according to claim 5, wherein the oxide layer on the donor substrate that is transferred to the SOI structure is an Ultra Thin Buried Oxide (UTBOX) layer having a thickness of between 50 and 1000 Å.

7. The method according to claim 6, wherein the UTBOX layer has a thickness that is less than 500 Å.

8. The method according to claim 2, wherein the receiver substrate is silicon.

9. The method according to claim 1, wherein the neutral gas is argon and the plasma activation is carried out at a power density of 0.4 W/cm².

10. The method according to claim 1, wherein the neutral gas is nitrogen and the plasma activation is carried out at a power density of 0.8 W/cm².

11. The method according to claim 2, which further comprises subjecting the receiver substrate, the oxide surface of the donor wafer, or both to a cleaning step before plasma activation.

12. The method according to claim 1, in that the thermal bonding treatment is carried out at a temperature of between about 200° C. and 600° C.

13. The method according to claim 12, wherein the thermal bonding treatment is carried out over a short duration of about 30 minutes to 5 hours.

14. An assembly for forming a Silicon on Insulator (SOI) structure which comprises first and second substrates of semiconductor materials, wherein a first substrate includes an oxide layer forming a surface of the substrate and having been plasma activated under an atmosphere containing oxygen; and the second substrate has a surface that has been plasma activated under an inert atmosphere; wherein the surfaces are molecularly bonded together by contacting their plasma activated surfaces together and conducting a thermal treatment to form a bonded structure that provides enhanced bonding compared to a bonded structure of the same substrates where each surface is plasma activated in the same manner, so that the structure includes an Ultra Thin Buried Oxide (UTBOX) layer having a thickness of between 50 and 1000 Å.

15. The assembly according to claim 14, wherein the thickness of the UTBOX layer is less than 500 Å.

16. The assembly according to claim 14, wherein the substrate that includes the surface oxide layer is a donor substrate for supplying a useful layer of the semiconductor material and the oxide layer and the second substrate is a receiver substrate that receives the useful and oxide layers.

17. The assembly according to claim 16, wherein the donor wafer includes a zone of weakness that can be split to remove the donor wafer except for the useful and UTBOX layers that are transferred to the receiver substrate to form the SOI structure.

18. The SOI structure according to claim 17 having an UTBOX layer of approximately 250 Å and between 0 and 10 defects.

19. The SOI structure according to claim 17 having an oxide layer of approximately 125 Å and between 0 and 310 defects.

20. The SOI structure according to claim 17 having an oxide layer of approximately 1000 Å and wherein the plasma activation under a neutral atmosphere was carried out with argon to provide a bonding energy at room temperature of approximately 0.175 J/m².

21. The SOI structure according to claim 17 having an oxide layer of approximately 500 Å and wherein the plasma activation under a neutral atmosphere was carried out with argon to provide a bonding energy at room temperature of approximately 0.180 J/m².

22. The SOI structure according to claim 7 having an oxide layer of approximately 250 Å and wherein the plasma activation under a neutral atmosphere was carried out with argon to provide a bonding energy at room temperature of approximately 0.200 J/m².

23. The SOI structure according to claim 17 having an oxide layer of approximately 125 Å and wherein the plasma activation under a neutral atmosphere was carried out with argon to provide a bonding energy at room temperature of approximately 0.200 J/m².

24. The SOI structure according to claim 17 having an oxide layer of approximately 1000 Å and wherein the plasma activation under a neutral atmosphere was carried out with nitrogen argon to provide a bonding energy at room temperature of approximately 0.235 J/m².

25. The SOI structure according to claim 17 having an oxide layer of approximately 500 Å and wherein the plasma activation under a neutral atmosphere was carried out with nitrogen to provide a bonding energy at room temperature of approximately 0.258 J/m².

26. The SOI structure according to claim 17 having an oxide layer of approximately 250 Å and wherein the plasma activation under a neutral atmosphere was carried out with nitrogen to provide a bonding energy at room temperature of approximately 0.270 J/m².

27. The SOI structure according to claim 17 having an oxide layer of approximately 125 Å and wherein the plasma activation under a neutral atmosphere was carried out with argon to provide a bonding energy at room temperature of approximately 0.262 J/m².
